(19) United States
(12) Patent Application Publication
(10) Pub. No.: US 2026/0190909 A1
(43) Pub. Date: Jul. 2, 2026

(54) SUBSTRATE PROCESSING APPARATUS AND METHOD

(71) Applicant: SEMES CO., LTD., Cheonan-si (KR)

(72) Inventors: Jung Eun PARK, Gyeonggi-do (KR); Eun Jung LEE, Seoul (KR)

(73) Assignee: SEMES CO., LTD., Cheonan-si (KR)

(21) Appl. No.: 19/387,048

(22) Filed: Nov. 12, 2025

(30) Foreign Application Priority Data
Dec. 30, 2024 (KR) 10-2024-0201262

(51) Int. Cl. H01L 21/67; H01L 21/02; H01L 21/677

(52) U.S. Cl. CPC H10P 72/0424; H10P 90/126; H10P 72/0452; H10P 72/32

(57) ABSTRACT

There is provided a substrate processing apparatus in which the distribution of the amount of etching is improved. The substrate processing apparatus includes: a support stand configured to rotate a substrate; a first chemical solution supplier configured to supply a first chemical solution to the substrate; a second chemical solution supplier configured to supply a second chemical solution to the substrate; and a controller configured to control the support stand, the first chemical solution supplier, and the second chemical solution supplier, wherein the substrate includes a first region, including an edge of the substrate, and a second region arranged inward of the first region, and the controller is further configured to control, while rotating the support stand at a first speed, such that the first chemical solution supplier discharges the first chemical solution to the first region and the second chemical solution supplier discharges the second chemical solution to the second region, thereby performing etching in the first region while preventing etching in the second region, and to control, while rotating the support stand at a second speed higher than the first speed, such that the first chemical solution supplier discharges the first chemical solution to the second region, thereby performing etching on a front surface of the substrate.

### CROSS-REFERENCE TO RELATED APPLICATION

This application claims priority from Korean Patent Application No. 10-2024-0201262 filed on Dec. 30, 2024 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a substrate processing apparatus and method.

### 2. Description of the Related Art

In the manufacture of semiconductor devices or display devices, various processes such as photolithography, etching, ashing, ion implantation, thin film deposition, and cleaning processes are performed. The etching process includes a dry etching process using plasma and a wet etching process using an etching solution. In wet etching, a substrate can be etched by rotating the substrate while discharging etching solution onto the surface of the substrate. When the etching solution is discharged onto the central region of the substrate, its impact decreases and the thickness of the liquid film also decreases as it flows toward the edge region of the substrate, and the temperature of the etching solution drops. Accordingly, a difference arises between the amount of etching at the center region and at the edge region, that is, the distribution of the amount of etching is non-uniform.

### SUMMARY

An objective of the present disclosure is to provide a substrate processing apparatus in which the distribution of the amount of etching is improved.

Another objective of the present disclosure is to provide a substrate processing method in which the distribution of the amount of etching is improved.

The objectives of the present disclosure are not limited to those mentioned above, and other objectives not explicitly stated will be clearly understood by those skilled in the art based on the following description.

According to an aspect of the present disclosure, a substrate processing apparatus includes: a support stand configured to rotate a substrate; a first chemical solution supplier configured to supply a first chemical solution to the substrate; a second chemical solution supplier configured to supply a second chemical solution to the substrate; and a controller configured to control the support stand, the first chemical solution supplier, and the second chemical solution supplier, wherein the substrate includes a first region, including an edge of the substrate, and a second region arranged inward of the first region, and the controller is further configured to control, while rotating the support stand at a first speed, such that the first chemical solution supplier discharges the first chemical solution to the first region and the second chemical solution supplier discharges the second chemical solution to the second region, thereby performing etching in the first region while preventing etching in the second region, and to control, while rotating the support stand at a second speed higher than the first speed, such that the first chemical solution supplier discharges the first chemical solution to the second region, thereby performing etching on a front surface of the substrate.

According to another aspect of the present disclosure, a substrate processing apparatus includes: a support stand configured to rotate a substrate; an etching solution supplier configured to supply an etching solution to the substrate; a pure water supplier configured to supply pure water to the substrate; and a controller configured to control the support stand, the etching solution supplier, and the pure water supplier, wherein the substrate includes a first region, including an edge of the substrate, and a second region, including a center of the substrate, and the controller is further configured to control, while rotating the support stand at a second speed higher than a first speed, such that the pure water supplier discharges the pure water to the second region, thereby wetting a front surface of the substrate, to thereafter control, while rotating the support stand at the first speed, such that the etching solution supplier discharges the etching solution to the first region and the pure water supplier discharges the pure water to the second region, thereby performing etching in the first region while preventing etching in the second region, to thereafter control, while rotating the support stand at the second speed, such that the etching solution supplier discharges the etching solution to the second region, thereby etching a front surface of the substrate, and to thereafter control, while rotating the support stand at the second speed, such that the pure water supplier discharges the pure water to the second region, thereby rinsing the front surface of the substrate.

According to still another aspect of the present disclosure, a substrate processing method includes: providing a substrate processing apparatus including a support stand configured to rotate a substrate, a first chemical solution supplier configured to supply a first chemical solution to the substrate, and a second chemical solution supplier configured to supply a second chemical solution to the substrate; while rotating the support stand at a first speed, discharging, by the first chemical solution supplier, the first chemical solution to a first region of the substrate on the support stand and discharging, by the second chemical solution supplier, the second chemical solution to a second region of the substrate on the support stand, thereby performing etching in the first region while preventing etching in the second region; and while rotating the support stand at a second speed higher than the first speed, discharging, by the first chemical solution supplier, the first chemical solution to the second region of the substrate, thereby performing etching on a front surface of the substrate.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing exemplary embodiments thereof in detail with reference to the attached drawings, in which:

FIG. 1 is a conceptual diagram illustrating a substrate processing system according to some embodiments of the present disclosure;

FIG. 2 is a plan view illustrating a substrate processing apparatus according to some embodiments of the present disclosure;

FIG. 3 is a cross-sectional view illustrating the substrate processing apparatus according to some embodiments of the present disclosure;

FIG. 4 is a plan view illustrating a plurality of regions of a substrate;

FIG. 5 is a diagram illustrating a substrate processing method according to some embodiments of the present disclosure;

FIGS. 6 to 8 are diagrams for explaining intermediate steps of the substrate processing method of FIG. 5;

FIG. 9 is a plan view illustrating a plurality of regions of the substrate;

FIG. 10 is a diagram for explaining intermediate steps of the substrate processing method according to some embodiments of the present disclosure; and

FIGS. 11 and 12 are diagrams for explaining intermediate steps of the substrate processing method according to some embodiments of the present disclosure.

### DETAILED DESCRIPTION

Hereinafter, preferred embodiments of the present disclosure will be described in detail with reference to the accompanying drawings. The advantages and features of the present disclosure, and methods of achieving them, will be apparent from the embodiments described below in detail with reference to the drawings. However, the present disclosure is not limited to the embodiments disclosed herein but may be embodied in various forms. Rather, the embodiments are provided so that the present disclosure is complete and to fully convey the scope of the invention to those skilled in the art. The present disclosure is defined only by the claims. Throughout the specification, the same reference numerals denote the same elements.

Spatially relative terms such as “below,” “beneath,” “lower,” “above,” and “upper” may be used to conveniently describe the relationship of one element or component to another element or component as illustrated in the drawings. Spatially relative terms are intended to encompass different orientations of a device or element in use or operation in addition to the orientations depicted in the drawings. For example, if the device in the drawings is turned over, an element described as being “below” or “beneath” another element may be positioned “above” the other element. Thus, the exemplary term “below” may encompass both below and above directions. The device may also be oriented in other directions, and accordingly, spatially relative terms may be interpreted based on orientation.

Although the terms “first,” “second,” and the like may be used to describe various elements, components, and/or periods, these elements, components, and/or periods are not limited by such terms. These terms are used only to distinguish one element, component, or period from another. Accordingly, a first element, component, or period described below may be a second element, component, or period without departing from the scope of the present disclosure.

Hereinafter, embodiments of the present disclosure will be described in detail with reference to the accompanying drawings. In the description with reference to the drawings, the same reference numerals will be assigned to the same or corresponding elements regardless of figure numbers, and redundant descriptions thereof will be omitted.

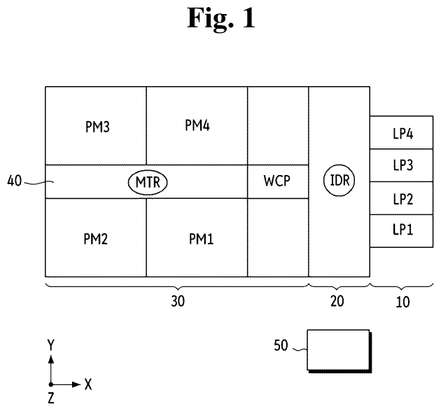

FIG. 1 is a conceptual view illustrating a substrate processing system according to some embodiments of the present disclosure.

Referring to FIG. 1, the substrate processing system according to some embodiments of the present disclosure includes a load port 10, an index module 20, a process module 30, a transfer module 40, and a controller 50. The load port 10, the index module 20, and the process module 30 may be arranged along a first direction (X-axis direction).

The load port 10 includes stages LP1 to LP4 on which containers storing a plurality of substrates are placed. The containers may be, for example, Front Opening Unified Pods (FOUP), Front Opening Shipping Boxes (FOSBs), or the like, but are not limited thereto. A plurality of stages may be arranged along a second direction (Y-axis direction). For example, four stages are illustrated.

The index module 20 is arranged between the load port 10 and the process module 30. For example, the index module 20 includes a rail installed inside an index chamber and an index robot IDR that moves along the rail. The index robot IDR, which includes an arm and a hand, picks up a substrate located at the load port 10 and transfers it to a buffer chamber WCP.

The process module 30 may include the buffer chamber WCP and a plurality of process chambers PM1 to PM4.

The buffer chamber WCP temporarily stores a substrate delivered by the index robot IDR of the index module 20. In addition, the buffer chamber WCP may temporarily store a substrate on which a predetermined process in at least one of the process chambers PM1 to PM4 has been completed.

The transfer module 40 is arranged to extend along the first direction (X direction). The transfer module 40 includes a guide rail inside, and a transfer robot MTR that moves along the guide rail is installed.

A pair of process chambers PM1 and PM2 may be arranged on one side of the transfer module 40 in the second direction (Y-axis direction), and another pair of process chambers PM3 and PM4 may be arranged on the other side of the transfer module 40. However, the present disclosure is not limited to this.

At least one of the process chambers PM1 to PM4, for example, the process chamber PM1, may be a liquid processing unit. The liquid processing unit may be configured to process a substrate by supplying a chemical solution to the substrate. The chemical solution may be, for example, an etchant, chemical, developer, rinse solution, or organic solvent.

The controller 50 controls the operations of the load port 10, the index module 20, the process module 30, and the transfer module 40.

The controller 50 may include: a process controller, which is a microprocessor (computer) that executes control of the substrate processing system; a user interface including a keyboard for operator input and a display for visualizing the operational status of a substrate processing apparatus; and a memory unit for storing a control program to execute processing under the control of the process controller, as well as various data, process conditions, and a program, i.e., a process recipe, for executing processing in each component of the substrate processing system in accordance with such data and process conditions. The user interface and memory unit may be connected to the process controller. The process recipe may be stored in a storage medium within the memory unit, and the storage medium may be a hard disk, a removable disk such as CD-ROM or DVD, or a semiconductor memory such as flash memory.

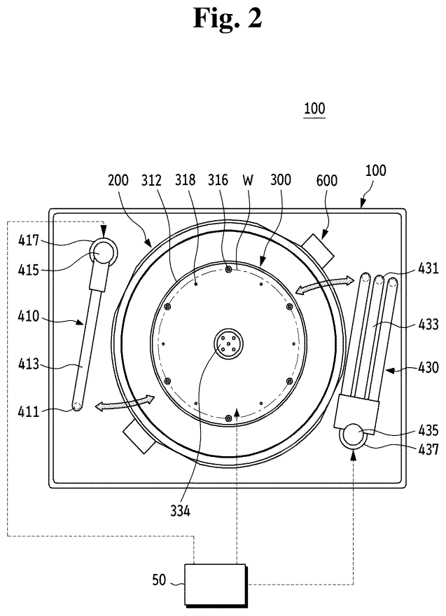

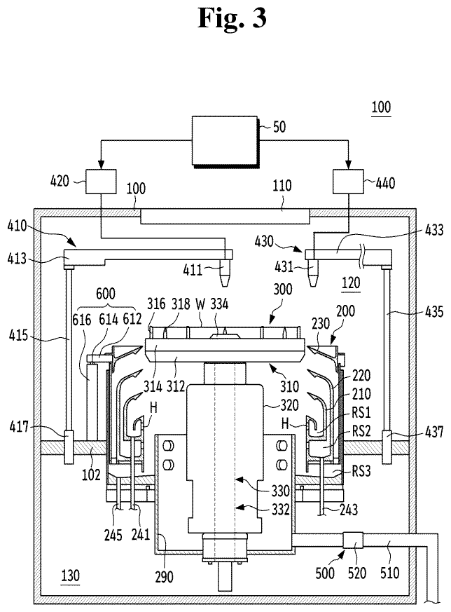

FIG. 2 is a plan view illustrating a substrate processing apparatus according to some embodiments of the present disclosure. FIG. 3 is a cross-sectional view illustrating a substrate processing apparatus according to some embodiments of the present disclosure.

Referring to FIGS. 2 and 3, a liquid processing unit 1000 includes a housing 100, a process container 200, a support stand 300, a first chemical solution supplier 410, a second chemical solution supplier 430, an exhaust unit 500, a lifting unit 600, and a controller 50. The controller 50 controls the support stand 300, the first chemical solution supplier 410, the second chemical solution supplier 430, the exhaust unit 500, and the lifting unit 600.

The housing 100 provides an enclosed interior space. An airflow supply member 110 is installed on the upper portion of the housing 100. The airflow supply member 110 forms a downward airflow inside the housing 100.

The airflow supply member 110 filters humid outside air. The humid outside air is supplied to the inside of the housing 100, forming a downward airflow. The downward airflow provides uniform air over the top of a substrate W, and discharges contaminants generated during processing of the surface of the substrate W by a processing fluid, to the exhaust unit 500 through first, second, and third recovery containers 210, 220, and 230 in the process container 200, together with the air.

The housing 100 is divided into a process region 120 and a maintenance region 130 by a horizontal partition 102. The process region 120 contains the process container 200 and support stand 300. The maintenance region 130 includes recovery lines 241, 243, and 245, an exhaust line 510 connected to the process container 200, as well as the drive unit of the lifting unit 600, the drive unit connected to the first chemical solution supplier 410, and supply lines. The maintenance region 130 is isolated from the process region 120.

The process container 200 has an open-topped cylindrical shape and an interior space for processing the substrate W. The open upper surface of the process container 200 serves as the entry and exit path for the substrate W. The support stand 300 is positioned within a processing space. The support stand 300 supports and rotates the substrate W during processing.

The process container 200 provides a lower space at its lower portion to which an exhaust duct 290 is connected for forced exhaust. A plurality of recovery containers 210, 220, and 230, which collect dispersed processing liquid and gas from the rotating substrate W, are arranged in stages within the process container 200.

Each of the first, second, and third recovery containers 210, 220, and 230 that are annular has exhaust openings H that communicate with a common annular space. Specifically, each of the first, second, and third recovery containers 210, 220, and 230 has a ring-shaped bottom and a cylindrical sidewall extending from the bottom. The second recovery container 220 surrounds and is spaced apart from the first recovery container 210. The third recovery container 230 surrounds and is spaced apart from the second recovery container 220.

The first, second, and third recovery containers 210, 220, and 230 provide recovery spaces RS1, RS2, and RS3 into which the processing liquid and fumes blown off from the substrate W flow. The first recovery space RS1 is defined by the first recovery container 110, the second recovery space RS2 is defined by the space between the first and second recovery containers 110 and 120, and the third recovery space RS3 is defined by the space between the second and third recovery containers 120 and 130.

The upper surfaces of the first, second, and third recovery containers 210, 220, and 230 are open in the center. Each of the first, second, and third recovery containers 210, 220, and 230 are formed with an inclined surface such that the distance from the sidewall to the opening of each of the first, second, and third recovery containers 210, 220, and 230 increases toward the opening. The processing liquid blown off the substrate W flows into the recovery spaces RS1, RS2, and RS3 along the upper surfaces of the first, second, and third recovery containers 210, 220, and 230.

A processing liquid entering the first recovery space RS1 is discharged through the first recovery line 241. A second processing liquid entering the second recovery space RS2 is discharged through the second recovery line 243. A third processing liquid entering the third recovery space RS3 is discharged through the third recovery line 245.

The support stand 300 supports the substrate W during processing and is able to rotate the substrate W during processing.

The support stand 300 includes a support plate 310, a spin driver 320, and a rear nozzle unit 330.

The support plate 310 includes a chuck stage 312 and a quartz window 314. The chuck stage 312 has a circular upper surface. The chuck stage 312 is coupled to the spin driver 320 for rotation. Chucking pins 316 are installed at the periphery of the chuck stage 312. The chucking pins 316 are provided to extend through the quartz window 314 and protrude above the quartz window 314. The chucking pins 316 align the substrate W supported by a plurality of support pins 318 for correct positioning. During processing, the chucking pins 316 prevent the substrate W from shifting out of position by contacting the side of the substrate W.

The quartz window 314 is located above the substrate W and the chuck stage 312. The quartz window 314 is provided to protect a lamp unit. The quartz window 314 may be transparent. The quartz window 314 may rotate with the chuck stage 312. The quartz window 314 includes the support pins 318. The support pins 318 are arranged at intervals around the upper edge of the quartz window 314. The support pins 318 are provided to protrude upward from the quartz window 314. The support pins 318 support the bottom surface of the substrate W with the substrate W spaced upward apart from the quartz window 314.

The spin driver 320 is hollow and coupled to the chuck stage 312 to rotate the chuck stage 312. When the chuck stage 312 rotates, the quartz window 314 may also rotate with the chuck stage 312. Some components inside the support plate 310 may be positioned independently of the rotation of the support plate 310.

The rear nozzle unit 330 applies rinse solution (e.g., deionized water (DIW)) to the back surface of the substrate W. The rear nozzle unit 330 includes a nozzle body 332 and a rear nozzle ejector 334. The rear nozzle ejector 334 is positioned above the center of the chuck stage 312 and quartz window 314. The nozzle body 332 extends through the hollow spin driver 320, and may have a rinse solution transit line, gas supply line, and purge gas supply line provided therein.

The exhaust unit 500 may exhaust the interior of the housing 100. For example, the exhaust unit 500 provides suction pressure for whichever of the first, second, and third recovery containers 210, 220, and 230 that collect processing liquid during processing. The exhaust unit 500 includes an exhaust line 510 connecting an exhaust duct and a damper 520. The exhaust line 510 receives exhaust pressure from an exhaust pump and is connected to a main exhaust line embedded in the floor of a semiconductor production line.

The process container 200 is coupled to the lifting unit 600 that changes the vertical position of the process container 200. The lifting unit 600 moves the process container 200 linearly in a vertical direction. As the process container 200 moves vertically, the relative height between the support stand 300 and the process container 200 changes.

The lifting unit 600 includes a bracket 612, a moving shaft 614, and a driver 616. The bracket 612 is fixed to the outer wall of the process container 100. The moving shaft 614, which is moved up and down by the driver 616, is fixed to the bracket 612. When loading or unloading the substrate W onto the support stand 300, the process container 200 is lowered so that the support stand 300 protrudes above the process container 200. During processing, the height of the process container 200 is adjusted to guide the processing liquid into its designated recovery container among the first, second, and third recovery containers 210, 220, and 230, depending on its type. The type of processing liquid to be recovered by each of the first, second, and third recovery containers 210, 220, and 230 and the type of contaminated gas to be recovered by each of the first, second, and third recovery spaces RS1, RS2, and RS3 may vary.

The first chemical solution supplier 410 may supply processing liquid, i.e., a first chemical solution, to the substrate W for processing. The supplier 410 may also supply heated processing liquid.

The first chemical solution supplier 410 may include a nozzle 411, a nozzle arm 413, a support rod 415, and a nozzle driver 417. The nozzle 411 receives processing liquid from a supply unit 420. The nozzle 411 discharges the received processing liquid onto the substrate W. The nozzle arm 413, which is an elongated arm in one direction, has the nozzle 411 mounted at its front end. The nozzle arm 413 supports the nozzle 411. The support rod 415 is attached to the rear end of the nozzle arm 413. The support rod 415 is positioned below the nozzle arm 413. The support rod 415 is arranged perpendicular to the nozzle arm 413. The nozzle driver 417 is provided at the lower end of the support rod 415. The nozzle driver 417 rotates the support rod 415 around the longitudinal axis of the support rod 415. As the support rod 415 rotates, the nozzle arm 413 and nozzle 411 may swing about the support rod 415. The nozzle 411 may swing between the inside and outside of the process container 200. The nozzle 411 may discharge processing liquid while swinging between the center and edge regions of the substrate W.

The processing liquid supplied by the first chemical solution supplier 410 may be diluted hydrofluoric acid (DHF), but is not limited thereto.

The second chemical solution supplier 430 may include a plurality of nozzles 431, a plurality of nozzle arms 433 corresponding to the respective nozzles 431, a support rod 435, and a nozzle driver 437. The nozzles 431 may be arranged side-by-side in the radial direction of the support stand 300.

The nozzles 431 receive a second chemical solution (e.g., DIW) via a supply unit 440. The nozzles 431 discharge the second chemical solution onto the surface of the substrate W. The nozzle arms 433, which are elongated arms in one direction, have the respective nozzles 431 at their front ends. The nozzle arms 433 support the nozzles 431. The support rod 435 is attached to the rear ends of the nozzle arms 433. The support rod 435 is positioned below the nozzle arms 433. The support rod 435 re arranged perpendicular to the nozzle arms 433. The support rod 435 is provided at the lower end of the support rod 435. The nozzle driver 437 rotates the support rod 435 about the longitudinal axis of the support rod 435. As the support rod 435 rotates, the nozzle arms 433 and the nozzles 431 swing the nozzle arms 433 and the nozzles 431 about the support rod 435. The nozzles 431 may swing between the inside and outside of the process container 200.

The second chemical solution supplier 430 may spray the second chemical solution (e.g., DIW) onto the entire surface of the substrate W supported on the support stand 300.

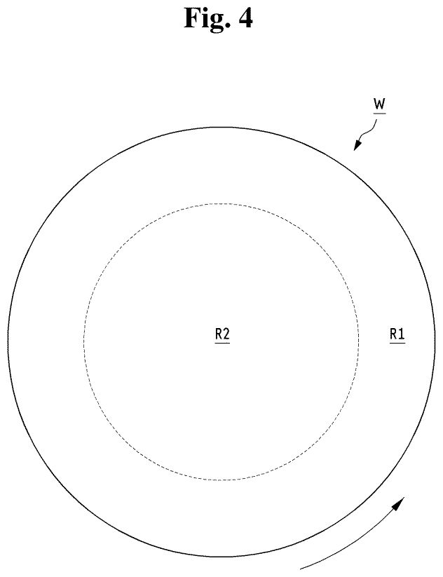

Hereinafter, a substrate processing method according to some embodiments of the present disclosure will be described with reference to FIGS. 4 to 8.

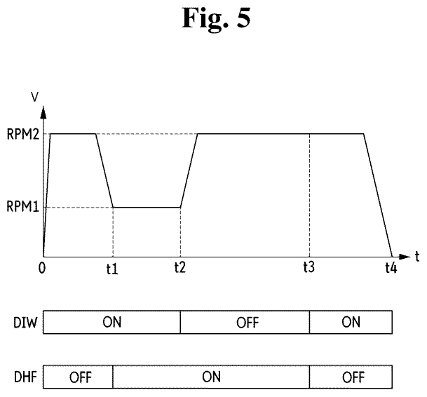

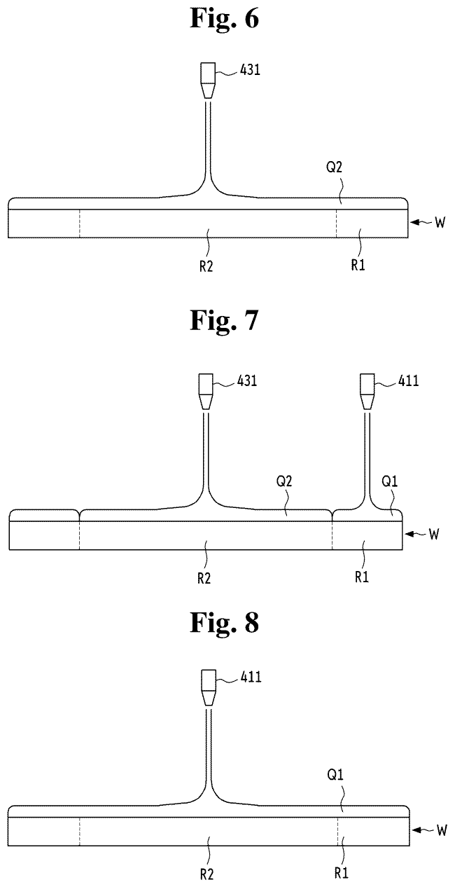

FIG. 4 is a plan view illustrating a plurality of regions of a substrate. FIG. 5 is a diagram for explaining the substrate processing method according to some embodiments of the present disclosure. FIGS. 6 to 8 are diagrams explaining intermediate steps of the substrate processing method of FIG. 5.

Referring to FIG. 4, a substrate W includes a first region R1, which includes the edge of the substrate W, and a second region R2, which is located inward relative to the first region R1. The second region R2 may include the center of the substrate W.

Referring to FIG. 5, the x-axis represents time, and the y-axis may represent the rotational speed of the substrate W (e.g., RPM).

From a time 0 to a time t1, when the substrate W is placed on the support stand 300, the support stand 300 begins to rotate. The speed of the support stand 300 increases to a second speed RPM2. The second speed RPM2 may be at least ten times higher than a first speed RPM1. For example, the second speed RPM2 may be 500 RPM, but is not limited thereto. As illustrated in FIG. 6, while the support stand 300 is rotating at the second speed RPM2, the second chemical solution supplier 430 (or nozzle 431) supplies the second chemical solution (e.g., DIW) to the second region R2 of the substrate W. A liquid film Q2 formed by the second chemical solution covers the front surface of the substrate W. As a result, the front surface of the substrate W is wet.

From the time t1 to a time t2, the rotational speed of the substrate W decreases to the first speed RPM1. The first speed RPM1 may be, for example, 10 RPM, but is not limited thereto. The first speed RPM1 may be a puddle speed, but is not limited thereto. As illustrated in FIG. 7, while the support stand 300 rotates at the first speed RPM1, the first chemical solution supplier 410 (or nozzle 411) supplies the first chemical solution (e.g., DHF) to the first region R1 of the substrate W. In addition, the second chemical solution supplier 430 (or nozzle 431) supplies the second chemical solution (e.g., DIW) to the second region R2 of the substrate W. The supply of the first chemical solution by the first chemical solution supplier 410 and the supply of the second chemical solution by the second chemical solution supplier 430 may be performed simultaneously.

A liquid film Q1 formed by the first chemical solution covers the first region R1, and a liquid film Q2 formed by the second chemical solution covers the second region R2. Since the substrate W rotates at the puddle speed, the boundary between the liquid films Q1 and Q2 may remain stable during rotation. The liquid film Q2 formed on the second region R2 prevents etching in the second region R2 while etching proceeds in the first region R1.

From the time t2 to a time t3, the rotational speed of the substrate W again increases to a third speed. The third speed may be the same as the second speed RPM2, but is not limited thereto.

While rotating the support stand 300 at the third speed, the first chemical solution supplier 410 (or nozzle 411) supplies the first chemical solution (e.g., DHF) to the second region R2 of the substrate W. Even when supplying the first chemical solution to the second region R2, the substrate W rotates at the high third speed, and thus, the liquid film Q1 formed by the first chemical solution covers the entire front surface of the substrate W. This ensures that etching proceeds uniformly over the entire front surface of the substrate W.

From the time t3 to a time t4, the rotational speed of the substrate W is maintained at a fourth speed. The fourth speed may be the same as the second speed RPM2, but is not limited thereto.

While rotating the support stand 300 at the fourth speed, the second chemical solution supplier 430 supplies the second chemical solution (e.g., DIW) to the second region R2. This operation rinses the front surface of the substrate W.

In the aforementioned substrate processing method, the second region R2 is blocked by the second chemical solution (e.g., DIW) during the period from the time t1 to the time t2. As a result, only the first region R1 is etched by the first chemical solution (e.g., DHF). As a result, the first region R1, including the edges, is etched during time t1 to t3, while the second region R2 undergoes etching during the period from the time t2 to the time t3.

If there is no step of etching only the first region R1 including the edge of the substrate W, a difference in etch amount may occur between the first region R1, including the edge of the substrate W, and the second region R2, including the central region of the substrate W. Since the aforementioned substrate processing method only includes the step of etching the first region R1 during the period from the time t1 to the time t2, the etch amounts in the first and second regions R1 and R2 may become substantially equal.

Also, depending on the recipe, the entire front surface of the substrate W may be etched first, and then etching only in the first region R1 may be performed while preventing etching in the second region R2.

Meanwhile, the length of the period from the time t1 to the time t2 may be set in advance to compensate for the etch amount in the first region R1. For example, if the etch amount in the first region R1 lacks 10 compared to the second region R2, the length of the period from the time t1 to the time t2 may be set to 10, and if the etch amount in the first region R1 lacks 20 units, the length of the period from the time t1 to the time t2 may be 20. The length of the period from the time t1 to the time t2 can thus be adjusted according to the etch amount compensation needed in the first region R1.

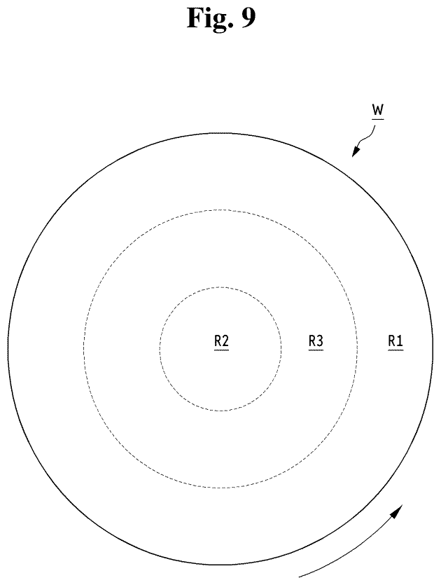

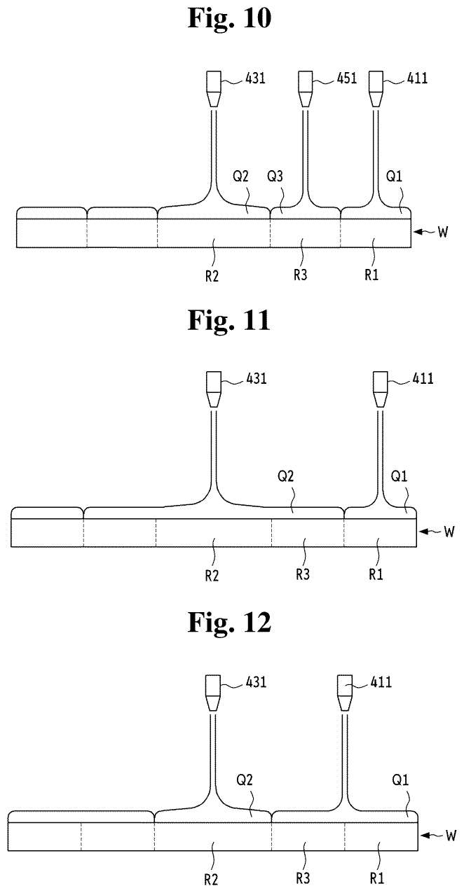

FIG. 9 is a plan view illustrating a plurality of regions of a substrate. FIG. 10 is a diagram explaining intermediate steps of the substrate processing method according to some embodiments of the present disclosure. Hereinafter, differences from the above description using FIGS. 4 to 8 will be mainly explained for convenience.

In FIGS. 4 to 8, the etch amount in the edge region of a substrate W is compensated for to match the etch amount in the center region of the substrate W.

In contrast, in FIGS. 9 and 10, the etch amount in the edge and middle regions of the substrate W are compensated for, thereby balancing the etch amounts in the edge, middle, and center regions of the substrate W.

Specifically, referring to FIG. 9, the substrate W includes a first region R1, including the edge of the substrate W, a second region R2 located inward from the first region R1 and including the center of the substrate W, and a third region R3 (or middle region) positioned between the first and second regions R1 and R2.

Referring to FIG. 10, while rotating the substrate W at the first speed RPM1 (or puddle speed), the first chemical solution supplier 410 (or nozzle 411) discharges the first chemical solution to the first region R1, the second chemical solution supplier 430 (or nozzle 431) discharges the second chemical solution to the second region R2, and a third chemical solution supplier (or nozzle 451) discharges a third chemical solution to the third region R3. Liquid films Q1, Q2, and Q3 formed by the first, second, and third chemical solutions, respectively, cover the first, second, and third regions R1, R2, and R3, respectively. For example, the first chemical solution may be more acidic than the third chemical solution. Thus, if the liquid films Q1 and Q3 are formed over the same duration, the etch amount caused by the first chemical solution may exceed that caused by the third chemical solution. This allows the etch amounts in the first, second, and third regions to be substantially equal.

Thereafter, the first chemical solution is discharged over the entire front surface of the substrate W to induce etching across the entire front surface of the substrate W.

FIGS. 11 and 12 are diagrams for explaining intermediate steps of the substrate processing method according to some embodiments of the present disclosure. Hereinafter, differences from the steps explained with reference to FIGS. 9 and 10 will be mainly described for convenience.

In FIG. 10, three nozzles 411, 431, and 451 are used to even the etch amounts across the three regions R1, R2, and R3.

In FIGS. 11 and 12, two nozzles 411 and 431 are used to even the etch amounts across the three regions R1, R2, and R3.

Referring to FIG. 11, while the support stand 300 rotates at the first speed RPM1, the first chemical solution supplier 410 (or nozzle 411) supplies the first chemical solution (e.g., DHF) to the first region R1. The second chemical solution supplier 430 (or nozzle 431) supplies the second chemical solution (e.g., DIW) to the second and third regions R2 and R3. In this manner, etching in the first region R1 is performed, while preventing etching in the second and third regions R2 and R3.

Thereafter, referring to FIG. 12, while the support stand 300 rotates at the first speed RPM1, the first chemical solution supplier 410 (or nozzle 411) supplies the first chemical solution (e.g., DHF) to the first region R1 and/or the third region R3. The second chemical solution supplier 430 (or nozzle 431) supplies the second chemical solution (e.g., DIW) to the second region R2. In this manner, etching in the first and third regions R1 and R3 is performed while preventing etching in the second region R2.

In other words, etching in the first region R1 is performed twice, and etching in the third region R3 is performed once, while preventing etching in the second region R2. In this manner, the etch amounts across the three regions R1, R2, and R3 can become even.

Although embodiments of the present disclosure have been described above with reference to the accompanying drawings, one of ordinary skill in the art will understand that various modifications and other equivalent embodiments can be made without departing from the technical spirit or essential characteristics of the present disclosure. Accordingly, the above-described embodiments are to be understood as illustrative in all respects and not limiting.

What is claimed is:

1. A substrate processing apparatus comprising:
a support stand configured to rotate a substrate;
a first chemical solution supplier configured to supply a first chemical solution to the substrate;
a second chemical solution supplier configured to supply a second chemical solution to the substrate; and
a controller configured to control the support stand, the first chemical solution supplier, and the second chemical solution supplier,
wherein
the substrate includes a first region, including an edge of the substrate, and a second region arranged inward of the first region, and
the controller is further configured to control, while rotating the support stand at a first speed, such that the first chemical solution supplier discharges the first chemical solution to the first region and the second chemical solution supplier discharges the second chemical solution to the second region, thereby performing etching in the first region while preventing etching in the second region, and to control, while rotating the support stand at a second speed higher than the first speed, such that the first chemical solution supplier discharges the first chemical solution to the second region, thereby performing etching on a front surface of the substrate.

2. The substrate processing apparatus of claim 1, wherein the first speed is a puddle speed.

3. The substrate processing apparatus of claim 1, wherein the second speed is at least ten times higher than the first speed.

4. The substrate processing apparatus of claim 1, wherein the performing of etching in the first region while preventing etching in the second region includes simultaneously discharging the first and second chemical solutions from the first and second chemical solution suppliers, respectively.

5. The substrate processing apparatus of claim 1, wherein the performing of etching in the first region while preventing etching in the second region proceeds for a predetermined time for compensating for an etch amount in the first region.

6. The substrate processing apparatus of claim 1, wherein
the substrate further includes a third region arranged between the first and second regions, and
the controller is further configured to control, while rotating the support stand at the first speed, such that the first chemical solution supplier discharges the first chemical solution to the first and third regions and the second chemical solution supplier discharges the second chemical solution to the second region, thereby performing etching in the first and third regions while preventing etching in the second region.

7. The substrate processing apparatus of claim 1, further comprising:
a third chemical solution supplier configured to supply a third chemical solution to the substrate,
wherein
the substrate further includes a third region arranged between the first and second regions, and
the controller is further configured to control, while rotating the support stand at the first speed, such that the first chemical solution supplier discharges the first chemical solution to the first region, the third chemical solution supplier discharges the third chemical solution to the third region, and the second chemical solution supplier discharges the second chemical solution to the second region, thereby performing etching in the first and third regions while preventing etching in the second region.

8. The substrate processing apparatus of claim 1, wherein before the performing of etching in the first region while preventing etching in the second region, the controller is further configured to control, while rotating the support stand at a third speed higher than the first speed, such that the second chemical solution supplier discharges the second chemical solution to the second region, thereby wetting the front surface of the substrate.

9. The substrate processing apparatus of claim 1, wherein after the performing of etching on the front surface of the substrate, the controller is further configured to control, while rotating the support stand at a fourth speed higher than the first speed, such that the second chemical solution supplier discharges the second chemical solution to the second region, thereby rinsing the front surface of the substrate.

10. The substrate processing apparatus of claim 1, wherein
the first chemical solution is diluted hydrofluoric acid (DHF), and
the second chemical solution is deionized water (DIW).

11. A substrate processing apparatus comprising:
a support stand configured to rotate a substrate;
an etching solution supplier configured to supply an etching solution to the substrate;
a pure water supplier configured to supply pure water to the substrate; and
a controller configured to control the support stand, the etching solution supplier, and the pure water supplier,
wherein
the substrate includes a first region, including an edge of the substrate, and a second region, including a center of the substrate, and
the controller is further configured to control, while rotating the support stand at a second speed higher than a first speed, such that the pure water supplier discharges the pure water to the second region, thereby wetting a front surface of the substrate, to thereafter control, while rotating the support stand at the first speed, such that the etching solution supplier discharges the etching solution to the first region and the pure water supplier discharges the pure water to the second region, thereby performing etching in the first region while preventing etching in the second region, to thereafter control, while rotating the support stand at the second speed, such that the etching solution supplier discharges the etching solution to the second region, thereby etching a front surface of the substrate, and to thereafter control, while rotating the support stand at the second speed, such that the pure water supplier discharges the pure water to the second region, thereby rinsing the front surface of the substrate.

12. The substrate processing apparatus of claim 11, wherein the first speed is a puddle speed.

13. A substrate processing method comprising:
providing a substrate processing apparatus including a support stand configured to rotate a substrate, a first chemical solution supplier configured to supply a first chemical solution to the substrate, and a second chemical solution supplier configured to supply a second chemical solution to the substrate;
while rotating the support stand at a first speed, discharging, by the first chemical solution supplier, the first chemical solution to a first region of the substrate on the support stand and discharging, by the second chemical solution supplier, the second chemical solution to a second region of the substrate on the support stand, thereby performing etching in the first region while preventing etching in the second region; and
while rotating the support stand at a second speed higher than the first speed, discharging, by the first chemical solution supplier, the first chemical solution to the second region of the substrate, thereby performing etching on a front surface of the substrate.

14. The substrate processing method of claim 13, wherein the first speed is a puddle speed.

15. The substrate processing method of claim 13, wherein the second speed is at least ten times higher than the first speed.

16. The substrate processing method of claim 13, wherein the performing of etching in the first region while preventing etching in the second region comprises simultaneously performing the discharging of the first chemical solution by the first chemical solution supplier and the discharging of the second chemical solution by the second chemical solution suppler.

17. The substrate processing method of claim 13, wherein the performing of etching in the first region while preventing etching in the second region proceeds for a predetermined time for compensating for an etch amount in the first region.

18. The substrate processing method of claim 13, wherein
the substrate further includes a third region arranged between the first and second regions, and
the substrate processing method further includes, while rotating the support stand at the first speed, discharging, by the first chemical solution supplier, the first chemical solution to the first and third regions and discharging, by the second chemical solution supplier, the second chemical solution to the second region, thereby performing etching in the first and third regions while preventing etching in the second region.

19. The substrate processing method of claim 13, wherein
the substrate processing apparatus further includes a third chemical solution supplier configured to supply a third chemical solution to the substrate,
wherein
the substrate further includes a third region arranged between the first and second regions, and
the substrate processing method further comprises, while rotating the support stand at the first speed, discharging, by the first chemical solution supplier, the first chemical solution to the first region, discharging, by the third chemical solution supplier, the third chemical solution to the third region, and discharging, by the second chemical solution supplier, the second chemical solution to the second region, thereby performing etching in the first and third regions while preventing etching in the second region.

20. The substrate processing method of claim 13, further comprising:
before the performing of etching in the first region while preventing etching in the second region, discharging, by the second chemical solution supplier, the second chemical solution to the second region, while rotating the support stand at a third speed higher than the first speed, thereby wetting a front surface of the substrate.
